(19) United States
(12) Patent Application Publication
(10) Pub. No.: US 2026/0239907 A1
(43) Pub. Date: Aug. 13, 2026

(54) POLISHING COMPOSITIONS AND METHODS OF USE THEREOF

(71) Applicant: Fujifilm Electronic Materials U.S.A., Inc., North Kingstown, RI (US)

(72) Inventors: Alexei P. Leonov, Chandler, AZ (US); Changhong Wu, Mesa, AZ (US); Bin Hu, Chandler, AZ (US); Fernando Valadez, San Tan Valley, AZ (US); Jorge Rosales, JR., Chandler, AZ (US); Samuel S. Kim, Chandler, AZ (US); Sean P. Sigman, Gilbert, AZ (US); Mario Shelbourne Bryant, Apache Junction, AZ (US)

(21) Appl. No.: 19/530,473

(22) Filed: Feb. 5, 2026

Related U.S. Application Data
(60) Provisional application No. 63/756,354, filed on Feb. 10, 2025.

(51) Int. Cl. H10P 52/40

(52) U.S. Cl. CPC H10P 52/403

(57) ABSTRACT

This disclosure relates to a method that includes applying a polishing composition to a substrate including elemental silicon on a surface of the substrate; and bringing a pad into contact with the surface of the substrate and moving the pad in relation to the substrate. The polishing composition includes 1) at least one abrasive; 2) at least one silicon removal rate enhancer; 3) at least one compound that has a pKa of at least 10; 4) at least one pH adjusting agent; and 5) water, wherein the composition has a pH of at least 10.

### CROSS-REFERENCE TO RELATED APPLICATION

The present application claims priority to U.S. Provisional Application Ser. No. 63/756,354, filed on Feb. 10, 2025, the contents of which are hereby incorporated by reference in their entirety.

### FIELD OF THE DISCLOSURE

The present disclosure relates generally to polishing compositions, and methods for polishing semiconductor substrates using the compositions described herein. More particularly, the disclosure relates to polishing compositions and methods for removing elemental silicon from a semiconductor substrate.

### BACKGROUND OF THE DISCLOSURE

Chemical mechanical polishing compositions are used in the semiconductor industry in a process step called chemical mechanical polishing/planarization (CMP). Along with photolithographic patterning and deposition, CMP is one of the three key enabling process steps in integrated circuit (IC) manufacturing process flow. Modern ICs are built in a parallel fashion, typically, hundreds at a time, on the surface of a common silicon wafer substrate. Photolithography, deposition, CMP and multiple auxiliary steps, are iteratively applied to the wafer surface where the evolving IC structures are located, until the final IC device is finished, and the wafer is ready to be cut into individual dies (chips) for packaging.

One purpose of the CMP step in this technology process flow is to reduce the overburden from the preceding deposition step to a specified layer thickness determined by the integration scheme, and to create a flat wafer surface to enable subsequent photolithography steps. CMP achieves this by polishing the wafer surface in a mechanical polisher. The polishing process involves holding the wafer in a rotating chuck (called the polishing head) and pressing the wafer against a compliant, felt-like polishing pad rotating on the polishing table (the platen), with a pre-selected pressure (the downforce), while applying an abrasive containing slurry (i.e., a chemical mechanical polishing composition) between the wafer surface and the polishing pad.

Some of the generally desired performance metrics for a CMP process based on a specific chemical mechanical polishing composition are: 1) high removal rates related to fab throughput efficiency; 2) high polishing selectivity related to the ability of the CMP process to stop on certain materials chosen as stop layers within the device layer stack; 3) low levels of defects (scratches, debris, leftover abrasive particles) related to enhancing the final device yield; and 4) uniform material removal across the wafer surface, which is related to the resultant wafer being suitably flat for subsequent photolithography steps. Uniform material removal within the die and across the wafer is also important for within-the-die and within-the-wafer device performance reproducibility and reliability.

### SUMMARY OF THE DISCLOSURE

The present disclosure provides polishing compositions and methods for use thereof demonstrating very high removal rates (e.g., in excess of 10,000 Å/min) of elemental silicon (e.g., single crystal silicon). Moreover, most of the components of the polishing compositions described herein are generally of low health hazard (e.g., classified as a GHS Category 3 or above). In some embodiments, the polishing compositions of the disclosure contain no compounds with the health hazards not permitted in the CMP modules of semiconductor fabs (e.g., GHS Category 1 and 2 carcinogens, GHS Category 1 and 2 reproductive hazards, substances with GHS Category 1 and 2 acute toxicity, and GHS Category 1 and 2 sensitizers). In addition, the polishing compositions of the disclosure provide low cost of ownership (COO) by being at least 2× dilute-able.

In some embodiments, the disclosure features methods that include applying a polishing composition to a substrate comprising elemental silicon on a surface of the substrate and bringing a pad into contact with the surface of the substrate and moving the pad in relation to the substrate. The polishing compositions include 1) at least one abrasive; 2) at least one silicon removal rate enhancer; 3) at least one compound that has a pKa of at least 10; 4) at least one pH adjusting agent; and 5) water, wherein the composition has a pH of at least 10.

Such methods can be performed, for example, by A) placing the wafer in a polisher equipped with a polishing pad, and B) polishing the wafer with the polishing pad in the presence of a polishing composition described herein.

In some embodiments, the disclosure features polishing compositions including 1) at least one abrasive; 2) at least one silicon removal rate enhancer; 3) at least one compound that has a pKa of at least 10; 4) at least one pH adjusting agent; and 5) water, wherein the composition has a pH of at least 10.

### DETAILED DESCRIPTION OF THE DISCLOSURE

The polishing compositions and methods for use thereof set forth in this disclosure contain abrasives that are generally insoluble in water. Therefore, the compositions of the disclosure may be referred to as slurries. For the purposes of this disclosure, the terms “composition” and “slurry” and “compositions” and “slurries” are used interchangeably.

The polishing compositions described herein provide high removal rates (e.g., at least 10,000 Å/min) of elemental silicon (e.g., single crystal silicon), while employing components characterized by having low health hazards.

Without wishing to be bound by theory, it is believed that the high removal rates at least 10,000 Å/min) of elemental silicon (e.g., single crystal silicon), provided by the polishing compositions of the disclosure is achieved in part by the compound that has a pKa of at least 10, as it maintains a sufficiently high pH of the polishing composition for optimal polishing performance.

In some embodiments, the disclosure features methods that include applying a polishing composition to a substrate comprising elemental silicon on a surface of the substrate and bringing a pad into contact with the surface of the substrate and moving the pad in relation to the substrate. The polishing compositions include 1) at least one abrasive; 2) at least one silicon removal rate enhancer; 3) at least one compound that has a pKa of at least 10; 4) at least one pH adjusting agent; and 5) water, wherein the composition has a pH of at least 10.

In some embodiments, the methods featured in this disclosure effectively remove elemental silicon (e.g., single crystal silicon) from a substrate (e.g., a wafer substrate), in some cases at very high removal rates of elemental silicon (e.g., in excess of 10,000 Å/min). The methods featured in this disclosure can be performed, for example, by
A) placing the wafer in a polisher equipped with a polishing pad,
B) contacting the wafer with the polishing pad in the presence of a polishing composition described herein. In some embodiments, the polishing compositions can be diluted with DI water (e.g., at least 2-fold, at least 3-fold, at least 4-fold, at least 5-fold, or at least 10-fold) prior to the treating or contacting the substrate with the polishing compositions. Other components and/or steps used in the above CMP methods are either described below or are known in the art.

In some embodiments, the methods further include forming a semiconductor device from the substrate. In some embodiments, the removal rate of elemental silicon during the method is at least 10,000 Å/minute. In some embodiments, the removal rate of elemental silicon is maintained within a range of 10 percent throughout the processing of at least two hundred substrates with the method. In some embodiments, the elemental silicon is single crystal silicon. In some embodiments, the pad remains stain free throughout the processing of at least two hundred substrates with the method. In some embodiments, wherein the pH of the polishing composition remains at least 10 throughout the method.

In some embodiments, the disclosure features polishing compositions that include 1) at least one abrasive; 2) at least one silicon removal rate enhancer; 3) at least one compound that has a pKa of at least 10; 4) at least one pH adjusting agent; and 5) water, wherein the composition has a pH of at least 10.

In some embodiments, the silicon removal rate enhancer is selected from the group consisting of aminoalcohols, diamines, polyamines, hydrazines, and mixtures thereof. In some embodiments, the silicon removal rate enhancer is a compound of structure (I):

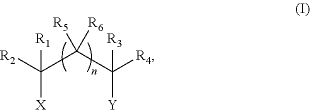

wherein:
   n is 0, 1, 2, or 3;
   each of X and Y, independently, is O(Rₐ), CH₂(Rₐ), or NH(Rₐ), provided that at least one of X and Y is O(Rₐ) or NH(Rₐ), in which each Rₐ, independently, is H or C₁-C₃ alkyl optionally substituted by hydroxyl or NH₂, and
each of R₁-R₆, independently, is H, OH, or C₁-C₃ alkyl optionally substituted by OH or NH₂.

As used herein, the term “C₁₋₃ alkyl” refers to a saturated hydrocarbon group that can be straight-chained or branched and can have 1 to 3 carbons, such as methyl, ethyl, propyl, or isopropyl.

In some embodiments, n in formula (I) is 0. In such embodiments, Y can be NH(Rₐ), in which Rₐ is H or C₁-C₃ alkyl optionally substituted by hydroxyl (e.g., hydroxylethyl); X can be O(Rₐ), in which Rₐ is H or C₁-C₃ alkyl optionally substituted by hydroxyl (e.g., hydroxylethyl); R₁ can be H; R₂ can be H or C₁-C₃ alkyl (e.g., methyl or ethyl); R₃ can be H, and R₄ can be H or C₁-C₃ alkyl (e.g., methyl). In some embodiments, when n is 0 and each of R₁-R₄ is H, at least one of X and Y is OH.

In some embodiments, n in formula (I) is 1. In such embodiments, Y can be NH(Rₐ), in which Rₐ is C₁-C₃ alkyl optionally substituted by hydroxyl (e.g., hydroxylethyl); X can be OH or NH₂; R₁ can be H; R₂ can be H; R₃ can be H; R₄ can be H; R₅ can be H or C₁-C₃ alkyl (e.g., methyl); and R₆ can be H, OH, and or C₁-C₃ alkyl (e.g., methyl or ethyl).

In some embodiments, at most one of R₁-R₄ or R₁-R₆ in formula (I) is OH or C₁-C₃ alkyl optionally substituted by OH or NH₂. For example, when n in formula (I) is 0, X is O(Rₐ), and Y is NH(Rₐ), R₁-R₃ can be H and R4 can be C₁-C₃ alkyl (e.g., methyl or ethyl) optionally substituted by OH or NH₂. Examples of such amines include 1-amino-2-propanol and 1-amino-2-butanol. In some embodiments, when X is NH(Rₐ) and Y is O(Rₐ), one of R₃ and R₄ is OH or C₁-C₃ alkyl optionally substituted by OH or NH₂; and the other of R₃ and R₄ is H.

In some embodiments, the silicon removal rate enhancer is an aminoalcohol. Exemplary aminoalcohols contemplated for use in the practice of the disclosure include, but are not limited to, monoethanolamine, diethanolamine, 1-amino-2-propanol, 1-amino-2-butanol, 1,3-diamino-2-propanol, 3-amino-1,2-propanediol, 3-amino-1-propanol, 2-(2-aminoethoxy)ethanol, 2-amino-3-methyl-1-butanol, 5-amino-1-pentanol, and the like.

In some embodiments, the silicon removal rate enhancer is a diamine. Exemplary diamines contemplated for use in the practice of the disclosure include, but are not limited to, 2,2-dimethyl-1,3-propane diamine, 1,3-diaminopentane, 2-(3-aminopropylamino)ethanol, and the like.

In some embodiments, the silicon removal rate enhancer is selected from the group consisting of 2-hydroxyethylhydrazine, 1-(2-aminoethyl)piperazine, 1-amino-4-methylpiperazine, 1,4-bis(3-aminopropyl)piperazine, bis(3-aminopropyl)amine, N,N-dimethyldipropylenetriamine, 3,3′-iminobis(N,N-dimethylpropylamine), 3,3′-diamino-N-methyldipropylamine, tris(3-aminopropyl)amine, 1-hydrazino-2-propanol, 2,2-dimethyl-1,3-propane diamine, 1,3-diaminopentane, N-methyl-1,3-diaminopropane, N,N′-dimethyl-1,3-propanediamine, bis(3-aminopropyl)amine, 1,4-Bis(3-aminopropyl)piperazine, and mixtures thereof.

In some embodiments, the silicon removal rate enhancer is in an amount of at least about 0.01 wt % (e.g., at least about 0.025 wt %, at least about 0.05 wt %, at least about 0.1 wt %, at least about 0.5 wt %, at least about 0.8 wt %, at least about 0.9 wt %, at least about 1 wt %, at least about 1.25 wt %, at least about 1.5 wt %, at least about 1.75 wt %, at least about 2 wt %, or at least about 2.5 wt %, at least about 3 wt %, at least about 4 wt %, at least about 5 wt %, at least about 6 wt %, at least about 7 wt %, or at least about 8 wt %) to at most about 15 wt % (e.g., at most about 12.5 wt %, at most about 10 wt %, at most about 7.5 wt %, at most about 5 wt %, at most about 4 wt %, at most about 3 wt %, or at most about 2 wt %) of the polishing composition, either in a concentrated form or in a diluted, point of use (POU) slurry.

In some embodiments, the compound that has a pKa of at least 10 has a pKa of at least 10.2 (e.g., at least 10.4, at least 10.6, at least 10.8, at least 11, at least 11.5, at least 12, or at most 12.5) to at most 14 (e.g., at most 13.5, at most 13, at most 12.8, at most 12.6, at most 12.4, at most 12.2, or at most 12). Without wishing to be bound by theory, it is believed that the compound that has a pKa of at least 10 allows for maintaining the pH above 10 during the polishing process so that precipitation of detrimental amounts of silicic acid polishing byproducts (e.g., silicic acid/silicate oligomer and polymeric species) is avoided.

In some embodiments, the compound that has a pKa of at least 10 is selected from the group consisting of imidazole, 1,2,4-triazole, 3-amino 1,2,4-triazole, 3,5-diamino-1,2,4-triazole, ethyl acetoacetate, malonitrile, 2,4-dimethylphenol, 2,4,6-trimethylphenol, methoxyphenol, ortho-creosol, 3-(cyclohexylamino)-1-propanesulfonic acid, 4-(cyclohexylamino)-1-butanesulfonic acid, proline, 5-aminovaleric acid, 6-aminocaproic acid, and mixtures thereof. In some embodiments, the compound that has a pKa of at least 10 is a compound of structure (II):

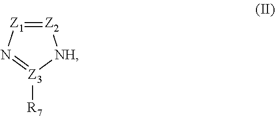

in which each of Z₁ and Z₂, independently, is —CR₈— or —N—, in which R₈ is H, N(R_{b})₂, COOH, C₁-C₃ alkyl; each R_{b}, independently, being H or C₁-C₃ alkyl; or Z₁ and Z₂ together form a 5-6 membered ring fused with the 5-membered ring in Structure (II); Z₃ is —C— or —N—; and R₇ is H, COOH, C₁-C₃ alkyl or N(R₉)₂, in which each R₉, independently, is H or C₁-C₃ alkyl; provided that, when Z₃ is —N—, R₇ is deleted. In some embodiments, when Z₃ in formula (II) is —C—, one of Z₁ and Z₂ can be —N—. In such embodiments, Z₁ can be —N—; Z₂ can be —CR₈—, in which R₈ is H or NH₂; and R₇ can be NH₂ or COOH. In some embodiments, when Z₃ in formula (II) is —C—, both of Z₁ and Z₂ can be —N—. In such embodiments, R₇ can be NH₂.

In some embodiments, the compound that has a pKa of at least 10 is a triazole. Exemplary triazoles contemplated for use in the practice of the disclosure include, but are not limited to, 1,2,4-triazole, 3-amino 1,2,4-triazole, 3,5-diamino-1,2,4-triazole, 1,2,4-triazole-3-carboxylic acid, and the like. It is understood that tautomeric forms of the azoles described herein rapidly interconvert in the aqueous/has a pKa of at least 10 is a phenol. Exemplary phenols contemplated for use in the practice of the disclosure include, but are not limited to, 2,4-dimethylphenol, 2,4,6-trimethylphenol, methoxyphenol, ortho-creosol, and the like.

In some embodiments, the compound that has a pKa of at least 10 is in an amount of at least about 0.01 wt % (e.g., at least about 0.05 wt %, at least about 0.1 wt %, at least about 0.4 wt %, at least about 0.5 wt %, at least about 0.6 wt %, at least about 0.7 wt %, at least about 0.8 wt %, at least about 0.9 wt %, at least about 1 wt %, at least about 1.25 wt %, at least about 1.5 wt %, at least about 1.75 wt %, at least about 2 wt %, at least about 3 wt %, at least about 4 wt %, at least about 5 wt %, at least about 6 wt %, or at least about 7 wt %) to at most about 15 wt % (e.g., at most about 12.5 wt %, at most about 10 wt %, at most about 7.5 wt %, at most about 5 wt %, at most about 4 wt %, at most about 3 wt %, at most about 2 wt %, at most about 1 wt %, at most about 0.9 wt %, at most about 0.8 wt %, at most about 0.7 wt %, at most about 0.6 wt %, at most about 0.5 wt %, or at most about 0.05 wt %) of the polishing composition, either in a concentrated form or in a diluted, point of use (POU) slurry.

In one or more embodiments, the polishing compositions of the disclosure can additionally contain at least one silicate dispersant. The silicate dispersant may be an anionic surfactant, a non-ionic surfactant, or a mixture thereof. Examples of the anionic surfactants preferably include carboxylate surfactants, sulfonate surfactants, phosphate surfactants, sulfate surfactants and mixtures thereof. In one or more embodiments, the anionic surfactant may include polyoxyethylene groups separating the anionic head group from an alkyl tail group. In some embodiments, the anionic surfactant may include between four and twenty polyoxyethylene groups. For example, the anionic surfactant may include at least four (e.g., at least six, or at least eight, or at least ten, or at least twelve) polyoxyethylene groups and at most twenty (e.g., at most eighteen, or at most sixteen, or at most fourteen, or at most twelve) polyoxyethylene groups.

The carboxylate surfactants are preferably those having a —CONR⁴— group in which R⁴ represents H or a methyl group. Examples of the carboxylate surfactants include N-acylamino acid salts (for example, coconut oil fatty acid sarcosine triethanolamine, lauroyl sarcosine potassium, oleyl sarcosine, and lauroyl methyl alanine sodium).

The sulfonate surfactants are preferably those having at least one group selected from the group consisting of a phenyl group, a —CONR⁵— group (in which R⁵ represents H or an alkyl group having 1 to 3 carbon atoms), and a —COO— group. Examples of the sulfonate surfactants include dodecylbenzenesulfonic acid, coconut oil fatty acid methyl taurine sodium, and dialkylsulfosuccinic acid and monoalkylsulfosuccinic acid (for example, sodium dioctyl sulfosuccinate, disodium sulfosuccinate to which 4 molecules of alkyl ether-polyoxyethylene having 12 to 14 carbon atoms were added, etc.).

The phosphate surfactants are preferably phosphate esters, and more preferably those having a polyoxyethylene group and/or a phenyl group. Examples of the phosphate surfactants include polyoxyethylene alkylphenyl ether phosphate and polyoxyethylene alkyl ether phosphate, such as lauryl ether sodium phosphate (to which 10 molecules of di-(polyoxyethylene were added) or di(alkyl ether phosphoric acid having 12 to 15 carbon atoms to which 2 molecules of polyoxyethylene were added).

The sulfate surfactants are preferably those having a polyoxyethylene group or a —CONR⁶— group (in which R⁶ represents H or a methyl group). Examples of the sulfate surfactants include polyoxyethylene coconut oil fatty acid monoethanol amide sodium sulfate and polyoxyethylene alkyl ether sulfate (for example, polyoxyethylene lauryl ether sodium sulfate or polyoxyethylene lauryl ether sulfuric acid triethanolamine).

In some embodiments, the silicate dispersant may be a non-ionic surfactant. In some embodiments, the non-ionic surfactant is a polysorbate. Exemplary polysorbates contemplated for use in the practice of the disclosure include, but are not limited to, polysorbate 20 (sorbitan monolaurate), polysorbate 40, polysorbate 60 (sorbitan monostearate), polysorbate 65, and polysorbate 80 (sorbitan monooleate). In some embodiments, the non-ionic surfactant is a polyetheramine. In some embodiments, the polyetheramine can be a compound of formula (III):

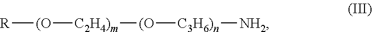

in which m is an integer from 0 to 40 representing the number of ethylene oxide groups; n is an integer from 0 to 40 representing the number of propylene oxide groups; R is a hydrocarbon chain, optionally substituted with a phenoxy group or an aryl group, or an NH₂ group. In some embodiments, the polyetheramine is triethylene glycol diamine, poly(ethyleneoxy)amine (e.g., JEFFAMINE® EDR-148 from Huntsman Corporation), poly(propyleneoxy)amine (e.g., JEFFAMINE® T-403 from Huntsman Corporation, Polyetheramine T-5000 from BASF), polyetheramine M-2005 (JEFFAMINE® M-2005), polyetheramine M-2070 (JEFFAMINE® M-2070), polyetheramine with a molecular weight of approximately 600 (e.g., Surfonamine® B-60), polyetheramine with a molecular weight of approximately 1000 (e.g., α-(2-Aminomethylethyl)-ω-(nonylphenoxy)-poly[oxy(methyl-1,2-ethanediyl, e.g., Surfonamine® B-100), or polyetheramine with a molecular weight of approximately 600 (e.g., Surfonamine® B-200).

Without wishing to be bound by theory, it is believed that the silicate dispersant as described herein improves dispersing the silicic acid/silicate byproducts that are produced during the polishing of elemental silicon. If the silicates are not adequately dispersed, they can precipitate/agglomerate and cause undesirable build-up on polishing pads, due to the large amount of silicon that can be removed during polishing of certain substrates (e.g., wafer substrates). The build-up can stain the pad, create defects on the polished substrate, and potentially affect the performance of processing further substrates with the same pad (i.e., reduce the pad lifetime).

In some embodiments, in which the silicate dispersant is a non-ionic surfactant, the non-ionic surfactant contemplated for use has an Hydrophilic-Lipophilic Balance (HLB) value of at least about 2 (e.g., at least about 3, at least about 4, at least about 5, at least about 6, at least about 7, at least about 8, or at least about 9) to at most about 17 (e.g., at most about 16, at most about 15, at most about 14, at most about 13, at most about 12, at most about 11, at most about 10, at most about 9, or at most about 8). In some embodiments, the non-ionic surfactant may include ionizable groups (e.g., amine groups) that remain non-ionized at the pH of the polishing composition (i.e., pH of 10 or higher).

In some embodiments, the at least one silicate dispersant is in an amount of from at least about 0.0001 wt % (e.g., at least about 0.001%, at least about 0.005%, at least about 0.01%, at least about 0.05%, at least about 0.1%, at least about 0.5%, at least about 2%, or at least about 3%) by weight to at most about 1% (e.g., at most about 0.5%, at most about 0.4%, at most about 0.3%, at most about 0.2%, at most about 0.1%, at most about 0.05%, or at most about 0.01%) by weight of the polishing composition described herein.

In some embodiments, the abrasives contemplated for use include alumina, fumed silica, colloidal silica, coated particles, titania, ceria, zirconia, and any combinations thereof. In some embodiments the abrasive is colloidal silica.

In addition, silica particles contemplated for use include sol-gel-derived colloidal silica without surface modification, and sol-gel-derived colloidal silica with surface modification. The surface modified silica can be anionically modified silica or cationically modified silica. The silica particles may include colloidal silica particles with isotropic spherical morphology characterized by primary particle diameter d1, or colloidal silica particles with aggregate morphology (predominantly fused dimers and trimers) characterized by primary and secondary particle diameters d1 and d2. In some embodiments, the silica morphology type is the aggregate morphology with primary particle diameter d1 of less than 80 nm but greater than 10 nm, and secondary particle diameter d2 of less than 160 nm but greater than 20 nm.

In some embodiments, the abrasive is in an amount of at least about 0.05 wt % (e.g., at least about 0.10 wt %, at least about 0.25 wt %, at least about 0.5 wt %, at least about 0.75 wt %, at least about 1 wt %, at least about 1.25 wt %, at least about 1.5 wt %, at least about 1.75 wt %, at least about 2 wt %, at least about 2.5 wt %, or at least about 3 wt %) to at most about 20 wt % (e.g., at most about 15 wt %, at most about 12.5 wt % at most about 10 wt %, at most about 7.5 wt %, at most about 5 wt %, at most about 4 wt %, at most about 3 wt %, at most about 2 wt %, or at most about 1 wt %) of the polishing composition, either in a concentrated form or in a diluted, point of use (POU) slurry.

In addition, in some embodiments, the polishing compositions of the disclosure can contain one or more additives, such as, pH adjusting agents, corrosion inhibitors, surfactants, organic solvents, and defoaming agents as optional components.

In some embodiments, the polishing compositions of the disclosure include at least one pH adjusting agent. The pH adjusting agent can bring the polishing compositions into the operational pH range. A variety of basic pH adjusting agents are contemplated for use, including, but not limited to, potassium hydroxide, ammonium hydroxide, sodium hydroxide, cesium hydroxide, triethanol amine, tetrabutyl ammonium hydroxide, or any combinations thereof.

In some embodiments, water is in an amount of at least about 50 wt % (e.g., at least about 55 wt %, at least about 60 wt %, at least about 65 wt %, at least about 70 wt %, at least about 75 wt %, at least about 80 wt %, at least about 85 wt %, at least about 90 wt %, at least about 95 wt %, or at least about 97 wt %) to at most about 99 wt % (e.g., at most about 95 wt %, at most about 90 wt %, at most about 85 wt %, at most about 75 wt %, at most about 70 wt %, at most about 65 wt %, at most about 60 wt %, or at most about 55 wt %) of the polishing composition, either in a concentrated form or in a diluted, point of use (POU) slurry.

In some embodiments, the polishing compositions of the disclosure can have a pH of at least about 10 (e.g., at least about 10.5, at least about 11, at least about 11.5, at least about 12, at least about 12.5, or at least about 13) to at most of 14 (e.g., at most about 13.5, at most about 13, at most about 12.5, at most about 12, at most about 11.5, or at most about 11). Without wishing to be bound by theory, it is believed that polishing compositions that do not have the above pH may not be able to achieve a stable and high removal rate of elemental silicon (e.g., over polishing at least 100 wafers) while showing no pad staining. Further, compositions with pH values above about 14 are highly susceptible to etching or dissolution of the abrasive particles leading to long term stability and storage problems.

Concentrate-ability (also referred to as “dilute-ability”) is one of the requirements set by the semiconductor manufacturers for any modern chemical mechanical polishing composition, intended to reduce the cost of ownership (COO) of the manufacturing consumable. The chemical mechanical polishing compositions described herein can be used as an at least 2×-dilutable concentrate mixture. In other words, the chemical mechanical polishing compositions can be diluted at least 2-fold (e.g., at least 3-fold, at least 4-fold, at least 5-fold, or at least 10-fold) prior to use by the end user. The chemical mechanical polishing compositions of the disclosure can include 0.05-20 weight percent (e.g., 2-3 weight percent) abrasives in a 2× concentrate composition mixture.

In some embodiments, when the polishing compositions of the disclosure are diluted, at least one oxidizing agent can be added to the composition. Oxidizing agents contemplated for use in the compositions of the disclosure include, but are not limited to, hydrogen peroxide, ammonium persulfate, silver nitrate (AgNO₃), ferric nitrates or chlorides, peracids or salts thereof, ozone water, potassium ferricyanide, potassium dichromate, potassium iodate, potassium bromate, vanadium trioxide, hypochlorous acid, sodium hypochlorite, potassium hypochlorite, calcium hypochlorite, magnesium hypochlorite, ferric nitrate, KMnO₄, other inorganic or organic peroxides, or mixtures thereof. In some embodiments, the oxidizing agent can be hydrogen peroxide. The oxidizing agent can be present in an amount of about 0.1 wt % to about 5 wt % (e.g., from about 0.4 wt % to about 2 wt %) of the composition, either in a concentrated form or in a diluted, point of use (POU) slurry. In some embodiments, the polishing compositions described herein can exclude the oxidizing agent described above.

In general, the polishing compositions of the disclosure can have a relatively high removal rate of elemental silicon (e.g., single crystal silicon, polysilicon, or amorphous silicon) and silicon germanium alloys (e.g., Si₁₋ₓGeₓ). In some embodiments, the polishing compositions of the disclosure can have a removal rate of elemental silicon of from at least about 10,000 Å/minute (e.g., at least about 10,500 Å/minute, at least about 11,000 Å/minute, at least about 11,500 Å/minute, at least about 12,000 Å/minute, at least about 12,500 Å/minute, at least about 13,000 Å/minute, at least about 13,500 Å/minute, at least about 14,000 Å/minute, at least about 14,500 Å/minute, at least about 15,000 Å/minute, at least about 16,000 Å/minute, at least about 17,000 Å/minute, at least about 18,000 Å/minute, at least about 19,000 Å/minute, or at least about 20,000 Å/minute) to at most about 30,000 Å/minute (e.g., at most about 29,000 Å/minute, at most about 28,000 Å/minute, at most about 27,000 Å/minute, at most about 26,000 Å/minute, at most about 25,000 Å/minute, at most about 24,000 Å/minute, at most about 23,000 Å/minute, at most about 22,000 Å/minute, at most about 21,000 Å/minute, at most about 20,000 Å/minute, at most about 19,000 Å/minute, at most about 18,000 Å/minute, at most about 17,000 Å/minute, at most about 16,000 Å/minute, at most about 15,000 Å/minute, at most about 14,000 Å/minute, at most about 13,000 Å/minute, at most about 12,000 Å/minute, or at most about 11,000 Å/minute). As mentioned herein, the removal rates of elemental silicon are measured at a polishing downforce pressure of 2.5 psi. In specific embodiments, the polishing compositions, methods, and removal rates described herein may be for single crystal silicon.

In some embodiments, the polishing compositions described herein can be substantially free of one or more of certain ingredients, such as organic solvents, pH adjusting agents, quaternary ammonium compounds (e.g., salts such as tetraalkylammonium salts or hydroxides such as tetraalkylammonium hydroxides, e.g., tetramethylammonium hydroxide or a salt thereof), quaternary phosphonium compounds (e.g., salts such as tetraalkylphosphonium salts or hydroxides such as tetraalkylphosphonium hydroxides) alkali bases (such as alkali hydroxides), bicarbonate salts (e.g., potassium bicarbonate or ammonium bicarbonate), carbonate salts (e.g., guanidine carbonate), fluorine containing compounds (e.g., fluoride compounds or fluorinated compounds (e.g., fluorinated polymers/surfactants)), silicon-containing compounds such as silanes (e.g., alkoxysilanes), nitrogen-containing compounds (e.g., amino acids, amines, imines (e.g., amidines such as 1,8-diazabicyclo[5.4.0]-7-undecene (DBU) and 1,5-diazabicyclo[4.3.0]non-5-ene (DBN)), amides, aminoalcohols, or imides), salts (e.g., halide salts or metal salts), polymers (e.g., nonionic, cationic, anionic, or water-soluble polymers), inorganic acids (e.g., hydrochloric acid, sulfuric acid, phosphoric acid, or nitric acid), surfactants (e.g., cationic surfactants, anionic surfactants, non-polymeric surfactants, or nonionic surfactants), plasticizers, oxidizing agents (e.g., H₂O₂ and/or periodic acid), corrosion inhibitors (e.g., azole or non-azole corrosion inhibitors), electrolytes (e.g., polyelectrolytes), dienoic acids (e.g., sorbic acid), abrasives (e.g., polymeric abrasives, fumed silica, ceria abrasives, nonionic abrasives, surface modified abrasives, negatively/positively charged abrasives, or ceramic abrasive composites), polyethylene glycols (e.g., PEG 1000, PEG 2000, PEG 4000, or PEG 8000), health hazardous chemicals classified as GHS Category 1 or 2 (e.g., ethylene diamine, piperazine, 1,3-diaminopropane, imidazole, 1,2,4-triazole, or 3-amino-1,2,4-triazole), and/or compounds having a boiling point less than 50° C. (e.g., propylamine or isopropylamine). The halide salts that can be excluded from the compositions include alkali metal halides (e.g., sodium halides or potassium halides) or ammonium halides (e.g., ammonium chloride), and can be fluorides, chlorides, bromides, or iodides. As used herein, an ingredient that is “substantially free” from a polishing composition refers to an ingredient that is not intentionally added into the composition. In some embodiments, the polishing composition described herein can have at most about 2000 ppm (e.g., at most about 1000 ppm, at most about 500 ppm, at most about 250 ppm, at most about 100 ppm, at most about 50 ppm, at most about 10 ppm, or at most about 1 ppm) of one or more of the above ingredients. In some embodiments, the polishing composition described herein can be completely free of one or more of the above ingredients.

In general, the components (e.g., the abrasives, the silicon removal rate enhancer, the compound that has a pKa of at least 10, the silicate dispersant, and the additives) of the polishing compositions described in this disclosure can be obtained from commercial sources or can be synthesized by methods known in the art.

The following examples are intended to further illustrate the subject matter of this disclosure and should in no way be construed as limiting the disclosure.

### EXAMPLES

Examples are provided to further illustrate the capabilities of the polishing compositions and methods of the present disclosure. The provided examples are not intended and should not be construed to limit the scope of the present disclosure. Any percentages listed are by weight (wt %) unless otherwise specified. The examples shown herein are representative and cannot encompass the complete broad scope of this invention disclosure.

The general polishing compositions used in the examples are shown in Table 1 below. The specifics details on the differences in the compositions tested will be explained in further detail when discussing the respective examples.

TABLE 1

| Component | % By Weight of Composition |
|---|---|
| Silicon Removal Rate Enhancer | 0.01-15 |
| Compound with pKa of at least 10 | 0.01-15 (if used) |
| Silicate Dispersant | 0.0001-1 (if used) |
| Solvent (DI Water) | 60-99.99 |
| Abrasive (SiO₂) | 0.05-20 |
| pH Adjusting Agent | 0.01-5 |
| pH | At least 10 |

### Example 1—Demonstration of Buffering by Polishing Waste pH Testing

This example demonstrates the utility of compounds that have a pKa of >about 10 to maintain a sufficiently high pH of the polishing composition for optimal polishing performance. Without being bound by theory it is believed that silicate species (e.g., silicic acid) are created during the polishing of elemental silicon substrates. The silicate species generated during the polishing process are more acidic than the initial polishing composition and their concentration in the polishing composition increases as the polishing progresses causing the overall pH of the polishing composition to decrease. Significantly, the silicate species generated during the polishing process are insoluble at pH values slightly below 10 and therefore any decrease in the pH of the polishing composition can lead to precipitation of the silicate species, which can reduce the lifetime of the polishing pad due to silicate build-up and potentially lead to silicon polishing rate decay as the polishing progresses. The results shown in Table 2 below show the pH of spent polishing compositions that were used to polish an elemental silicon wafer. The initial pH value of the polishing compositions was 10.5. The compositions included the same components with the exception that Compositions 1, 2, and 3 each included a different chemically distinct component that had a pKa above 10. The compound with a pKa above 10 in Composition 1 was an azole compound, the compound with a pKa above 10 in Composition 2 was an organic sulfonic acid compound, and the compound with a pKa above 10 in Composition 3 was an amino acid. Alternatively, Composition 4 included an azole compound that did not have a pKa above 10.

What is shown in the results is that Compositions 1-3 had their pH values effectively anchored to a pH above 10 where the silicate compounds remain soluble and do not noticeably affect the polishing process. However, in Composition 4 the pH value of the spent polishing composition shows a decrease in the pH to a value below about 10 and visible pad staining due to precipitation of the silicate species was visually observed on the pad after the polishing process.

TABLE 2

| | Spent pH Value | Pad Staining |
|---|---|---|
| Composition 1 | 10.23 | No |
| Composition 2 | 10.32 | No |
| Composition 3 | 10.3 | No |
| Composition 4 | 9.9 | Yes |

### Example 2—Demonstration of Silicate Residue Dispersion/Solubilization by Surfactant

This example demonstrates the utility of adding a silicate dispersant surfactant to the polishing composition to increase the dispersion/solubilization of residues formed during the polishing of elemental silicon substrates. As mentioned above, it is believed that silicate species are formed as byproduct/residue of the polishing of elemental silicon substrates. As these silicate species increase in concentration during the polish they can form oligomeric and amorphous structures that can precipitate from solution and cause issues relating to reduced polishing pad lifetime, pad staining, rate decay, etc. Surfactants and polymers were tested for their ability to disperse or solubilize the silicate polishing byproduct. Specifically, abrasive-free polishing compositions were spiked with a silicate precursor to simulate the silicate byproduct that is produced during polishing of a silicon substrate. The formulations were then aged overnight (e.g., about 14 hours) at 60° C. before the fluid was analyzed for Mean Particle Size (MPS) using Dynamic Light Scattering techniques. The results are shown in Table 3.

TABLE 3

| | | Mean Particle Size |
|---|---|---|
| | Surfactant/Polymer | (nm) |
| Composition 5 | None | 86.8 |
| Composition 6 | Water-Soluble Polymer (Acrylic | 130.3 |
| | Acid Copolymer) | |
| Composition 7 | Anionic Surfactant (aryl | 206.1 |
| | sulfonate) | |
| Composition 8 | Nonionic Surfactant | 71.1 |
| | (Acetylenic) | |
| Composition 9 | Nonionic Surfactant (Sorbitan | 69.8 |
| | Ester) | |
| Composition 10 | Water-Soluble Polymer (PEG) | 6573 |
| Composition 11 | Nonionic Surfactant (polyether | 58.5 |
| | monoamine) | |
| Composition 12 | Anionic Surfactant | 70.6 |
| | (ethoxylated alkyl phosphate) | |

What is shown in the results is that the addition of a nonionic surfactant to the polishing composition can effectively reduce the MPS measurements of the aged compositions when compared with control Composition 5 that does not include an additional surfactant/polymer additive. This result suggests that the nonionic surfactants are effective at dispersing/solubilizing silicate residues that are likely formed during the polishing of silicon substrates. Significantly, the water-soluble polymers tested (i.e., Compositions 6 and 10) and the aryl sulfonate anionic surfactant (i.e., Composition 7) actually increased the MPS measurement of aged compositions. Thus, a water-soluble polymer would likely not improve the polishing composition performance in the areas related to reducing byproduct agglomeration, pad staining, or reduced pad lifetime. Interestingly, the anionic surfactant of Composition 12 (an alkoxylated phosphate) did decrease the MPS measurement of aged compositions when compared with Composition 5 with no added silicate dispersant. This result suggests that surfactants having alkoxylated groups paired with an anionic head group may be more useful than an anionic surfactant that includes only an anionic group without alkoxylated groups (i.e., Composition 7).

### Example 3—Demonstration of Polishing Rate Stability

This Example demonstrates the importance of pH and the buffer component on polishing rate stability and pad staining. Two similar polishing compositions were formulated with the main difference being one formulation had a pH of 10 (Composition 13) and the other formulation had a pH of 10.75 (Composition 14). Each composition included an azole compound that has a pKa of 10.3. The polishing rates as the formulations were used to polish a total of 200 silicon wafers via an identical CMP process are shown in Table 4 below.

TABLE 4

| | Composition 13 | Composition 14 |
|---|---|---|
| | Silicon Removal Rate | Silicon Removal Rate |
| Silicon Wafer Number | (Å/min) | (Å/min) |
| 0 | 13792 | 13803 |
| 50 | 13858 | 13509 |
| 100 | 13369 | 13726 |
| 150 | 11404 | 14004 |
| 200 | 11014 | 13896 |

What is shown in the results is that the polishing rate for Composition 13 decayed as the process of polishing 200 wafers progressed. Specifically, the polishing rate at the end of the process of polishing 200 wafers was about 20 percent lower than the initial polishing rate for Composition 13. In contrast, the polishing rate for Composition 14 stayed relatively steady and in accord with the initial observed polishing rate without showing any signs of decay. Further, after 100 wafers the pad used with Composition 13 started showing visible signs of pad staining with silicate residue, while the pad used with Composition 14 remained stain free. It is believed that because the pH of Composition 13 started below the pKa of the buffering compound the buffering action was ineffective in countering the pH drop resulting from the production of silicate/silicic acid species during the polishing of the silicon wafers. Thus, the silicon byproducts precipitated resulting in pad staining and the deterioration of the polishing rate. In contrast, Composition 14 started with a sufficiently high pH for the buffering compound to be effective at maintaining a pH necessary to keep the silicate/silicic acid species solubilized and incapable of causing pad stain or affecting rate stability.

### EMBODIMENTS

Although the present invention is defined in the claims, it should be understood that the present invention can also (alternatively) be defined in accordance with the following embodiments:

1. A polishing composition comprising:
1) at least one abrasive;
2) at least one silicon removal rate enhancer;
3) at least one compound that has a pKa of at least 10; and
4) water;
wherein the composition has a pH of at least 10.

2. The composition of embodiment 1, wherein the silicon removal rate enhancer is selected from the group consisting of aminoalcohols, diamines, polyamines, hydrazines, and mixtures thereof.

3. The composition of embodiment 2, wherein the silicon removal rate enhancer is at least one compound of structure (I):

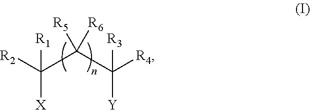

wherein:
   n is 0, 1, 2, or 3;
   each of X and Y, independently, is O(Rₐ), CH₂(Rₐ), or NH(Rₐ), provided that at least one of X and Y is O(Rₐ) or NH(Rₐ), in which each Rₐ, independently, is H or C₁-C₃ alkyl optionally substituted by hydroxyl or NH₂, and
   each of R₁-R₆, independently, is H, OH, or C₁-C₃ alkyl optionally substituted by OH or NH₂.

4. The composition of embodiment 2, wherein the silicon removal rate enhancer is selected from the group consisting of monoethanolamine, diethanolamine, 1-amino-2-propanol, 1-amino-2-butanol, 1,3-diamino-2-propanol, 3-amino-1,2-propanediol, 3-amino-1-propanol, 2-(2-aminoethoxy)ethanol, 2-amino-3-methyl-1-butanol, 5-amino-1-pentanol, 2-hydroxyethylhydrazine, 1-(2-aminoethyl)piperazine, 1-amino-4-methylpiperazine, 1,4-bis(3-aminopropyl)piperazine, bis(3-aminopropyl)amine, N,N-dimethyldipropylenetriamine, 3,3′-iminobis(N,N-dimethylpropylamine), 3,3′-diamino-N-methyldipropylamine, tris(3-aminopropyl)amine, 1-hydrazino-2-propanol, 2,2-dimethyl-1,3-propane diamine, 1,3-diaminopentane, N-methyl-1,3-diaminopropane, N,N′-dimethyl-1,3-propanediamine, 2,2-dimethyl-1,3-propanediamine, 1,3-diaminopropane, 2-(3-aminopropylamino)ethanol, bis(3-aminopropyl)amine, 1,4-Bis(3-aminopropyl)piperazine, and mixtures thereof.

5. The composition of any one of embodiments 1-4, wherein the silicon removal rate enhancer is in an amount of from about 0.01 wt % to about 15 wt % of the composition.

6. The composition of any one of embodiments 1-5, wherein the compound that has a pKa of at least 10 is selected from the group consisting of imidazole, 1,2,4-triazole, 3-amino 1,2,4-triazole, 3,5-diamino-1,2,4-triazole, ethyl acetoacetate, malonitrile, 2,4-dimethylphenol, 2,4,6-trimethylphenol, methoxyphenol, ortho-creosol, 3-(cyclohexylamino)-1-propanesulfonic acid, 4-(cyclohexylamino)-1-butanesulfonic acid, proline, 5-aminovaleric acid, 6 aminocaproic acid, and mixtures thereof.

7. The composition of any one of embodiments 1-6, wherein the compound that has a pKa of at least 10 is in an amount of from about 0.01 wt % to about 15 wt % of the composition.

8. The composition of any one of embodiments 1-7, wherein the abrasive is selected from the group consisting of alumina, silica, titania, ceria, zirconia, co-formed products of alumina, silica, titania, ceria, or zirconia, coated abrasives, surface modified abrasives, and mixtures thereof.

9. The composition of any one of embodiments 1-8, wherein the abrasive is in an amount of from about 0.05 wt % to about 20 wt % of the composition.

10. The composition of any one of embodiments 1-9, wherein the composition further comprises at least one silicate dispersant selected from the group consisting of non-ionic surfactants, anionic surfactants, and mixtures thereof.

11. The composition of embodiment 10, wherein the at least one silicate dispersant is a non-ionic surfactant, and wherein the non-ionic surfactant has an HLB value between about 2 to about 17.

12. The composition of embodiment 10, wherein the at least one silicate dispersant comprises a non-ionic surfactant selected from a polysorbate and a polyetheramine.

13. The composition of embodiment 12, wherein the polysorbate is selected from the group consisting of polysorbate 20 (sorbitan monolaurate), polysorbate 40, polysorbate 60 (sorbitan monostearate), polysorbate 65, and polysorbate 80 (sorbitan monooleate).

14. The composition of embodiment 12, wherein the polyetheramine is a compound of formula (III):

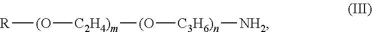

in which m is an integer from 0 to 40 representing the number of ethylene oxide groups; n is an integer from 0 to 40 representing the number of propylene oxide groups; R is a hydrocarbon chain, optionally substituted with a phenoxy group or an aryl group, or an NH₂ group.

15. The composition of embodiment 12, wherein the polyetheramine is selected from the group consisting of diethylene glycol diamine, poly(ethyleneoxy)amine (e.g., JEFFAMINE© EDR-148), poly(propyleneoxy)amine (e.g., JEFFAMINE® T-403, Polyetheramine T-5000), polyetheramine M-2005 (JEFFAMINE® M-2005), polyetheramine M-2070 (JEFFAMINE® M-2070), Surfonamine® B-60, α-(2-Aminomethylethyl)-ω-(nonylphenoxy)-poly[oxy(methyl-1,2-ethanediyl (Surfonamine® B-100), and Surfonamine® B-200.

16. The composition of embodiment 10, wherein the at least one silicate dispersant comprises an anionic surfactant selected from the group consisting of carboxylate surfactants, sulfonate surfactants, phosphate surfactants, sulfate surfactants and mixtures thereof.

17. The composition of embodiment 16, wherein the carboxylate surfactant is selected from the group consisting of coconut oil fatty acid sarcosine triethanolamine, lauroyl sarcosine potassium, oleyl sarcosine, and lauroyl methyl alanine sodium.

18. The composition of embodiment 16, wherein the sulfonate surfactant is selected from the group consisting of dodecylbenzenesulfonic acid, coconut oil fatty acid methyl taurine sodium, and sodium dioctyl sulfosuccinate.

19. The composition of embodiment 16, wherein the phosphate surfactant is selected from the group consisting of polyoxyethylene alkylphenyl ether phosphate and polyoxyethylene alkyl ether phosphate.

20. The composition of embodiment 16, wherein the sulfate surfactant is selected from the group consisting of polyoxyethylene coconut oil fatty acid monoethanol amide sodium sulfate and polyoxyethylene alkyl ether sulfate.

21. The composition of embodiment 10, wherein the at least one silicate dispersant is in an amount of from about 0.0001 wt % to about 1 wt % of the composition.

22. The composition of any one of embodiments 1-21, wherein the composition further comprises at least one pH adjusting agent.

23. The composition of embodiment 22, wherein the at least one pH adjusting agent is selected from organic bases, inorganic bases, or combinations thereof.

24. The composition of embodiment 22, wherein the at least one pH adjusting agent is in an amount of from about 0.01 wt % to about 5 wt % of the composition.

25. The composition of any one of embodiments 1-24, wherein the composition does not include an oxidizing agent.

26. A method, comprising:
applying the polishing composition of any one of embodiments 1-25 to a substrate comprising elemental silicon on a surface of the substrate; and
bringing a pad into contact with the surface of the substrate and moving the pad in relation to the substrate.

27. The method of embodiment 26, further comprising forming a semiconductor device from the substrate.

28. The method of embodiment 26 or 27, wherein the removal rate of elemental silicon during the method is at least 10,000 Å/minute.

29. The method of embodiment 28, wherein the removal rate of elemental silicon is maintained within a range of one percent throughout the processing of at least two hundred substrates with the method.

30. The method of any one of embodiments 26-29, wherein the pad remains stain free throughout the processing of at least two hundred substrates with the method.

31. The method of any one of embodiments 26-30, wherein the pH of the polishing composition remains at least 10 throughout the method.

While this disclosure has been described with respect to the examples and embodiments set forth herein, it is understood that other modifications and variations are possible without departing from the spirit and scope of the disclosure as defined in the appended claims.

What is claimed is:

1. A method, comprising:
applying a polishing composition to a substrate comprising elemental silicon on a surface of the substrate, the polishing composition comprising:
1) at least one abrasive,
2) at least one silicon removal rate enhancer,
3) at least one compound that has a pKa of at least 10,
4) at least one pH adjusting agent, and
5) water;
wherein the composition has a pH of at least 10.; and
bringing a pad into contact with the surface of the substrate and moving the pad in relation to the substrate.

2. The method of claim 1, further comprising forming a semiconductor device from the substrate.

3. The method of claim 1, wherein the removal rate of elemental silicon during the method is at least 10,000 Å/minute.

4. The method of claim 3, wherein the removal rate of elemental silicon is maintained within a range of one percent throughout the processing of at least two hundred substrates with the method.

5. The method of claim 1, wherein the pad remains stain free throughout the processing of at least two hundred substrates with the method.

6. The method of claim 1, wherein the pH of the polishing composition remains at least 10 throughout the method.

7. The method of claim 1, wherein the silicon removal rate enhancer is selected from the group consisting of aminoalcohols, diamines, polyamines, hydrazines, and mixtures thereof.

8. The method of claim 7, wherein the silicon removal rate enhancer is at least one compound of structure (1): 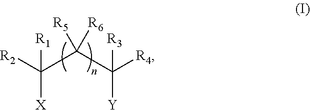
wherein:
n is 0, 1, 2, or 3;
each of X and Y, independently, is O(Rₐ), CH₂(Rₐ), or NH(Rₐ), provided that at least one of X and Y is O(Rₐ) or NH(Rₐ), in which each Rₐ, independently, is H or C₁-C₃ alkyl optionally substituted by hydroxyl or NH₂, and
each of R₁-R₆, independently, is H, OH, or C₁-C₃ alkyl optionally substituted by OH or NH₂.

9. The method of claim 7, wherein the silicon removal rate enhancer is selected from the group consisting of monoethanolamine, diethanolamine, 1-amino-2-propanol, 1-amino-2-butanol, 1,3-diamino-2-propanol, 3-amino-1,2-propanediol, 3-amino-1-propanol, 2-(2-aminoethoxy)ethanol, 2-amino-3-methyl-1-butanol, 5-amino-1-pentanol, 2-hydroxyethylhydrazine, 1-(2-aminoethyl)piperazine, 1-amino-4-methylpiperazine, 1,4-bis(3-aminopropyl)piperazine, bis(3-aminopropyl)amine, N,N-dimethyldipropylenetriamine, 3,3′-iminobis(N,N-dimethylpropylamine), 3,3′-diamino-N-methyldipropylamine, tris(3-aminopropyl)amine, 1-hydrazino-2-propanol, 2,2-dimethyl-1,3-propane diamine, 1,3-diaminopentane, N-methyl-1,3-diaminopropane, N,N′-dimethyl-1,3-propanediamine, 2,2-dimethyl-1,3-propanediamine, 1,3-diaminopropane, 2-(3-aminopropylamino)ethanol, bis(3-aminopropyl)amine, 1,4-Bis(3-aminopropyl)piperazine, and mixtures thereof.

10. The method of claim 1, wherein the silicon removal rate enhancer is in an amount of from about 0.01 wt % to about 15 wt % of the composition.

11. The method of claim 1, wherein the compound that has a pKa of at least 10 is selected from the group consisting of imidazole, 1,2,4-triazole, 3-amino 1,2,4-triazole, 3,5-diamino-1,2,4-triazole, ethyl acetoacetate, malonitrile, 2,4-dimethylphenol, 2,4,6-trimethylphenol, methoxyphenol, ortho-creosol, 3-(cyclohexylamino)-1-propanesulfonic acid, 4-(cyclohexylamino)-1-butanesulfonic acid, proline, 5-aminovaleric acid, 6 aminocaproic acid, and mixtures thereof.

12. The method of claim 1, wherein the compound that has a pKa of at least 10 is in an amount of from about 0.01 wt % to about 15 wt % of the composition.

13. The method of claim 1, wherein the abrasive is selected from the group consisting of alumina, silica, titania, ceria, zirconia, co-formed products of alumina, silica, titania, ceria, or zirconia, coated abrasives, surface modified abrasives, and mixtures thereof.

14. The method of claim 1, wherein the abrasive is in an amount of from about 0.05 wt % to about 20 wt % of the composition.

15. The method of claim 1, wherein the composition further comprises at least one silicate dispersant selected from the group consisting of non-ionic surfactants, anionic surfactants, and mixtures thereof.

16. The method of claim 15, wherein the at least one silicate dispersant is a non-ionic surfactant, and wherein the non-ionic surfactant has an HLB value between about 2 to about 17.

17. The method of claim 15, wherein the at least one silicate dispersant comprises a non-ionic surfactant selected from a polysorbate and a polyetheramine.

18. The method of claim 17, wherein the polysorbate is selected from the group consisting of polysorbate 20 (sorbitan monolaurate), polysorbate 40, polysorbate 60 (sorbitan monostearate), polysorbate 65, and polysorbate 80 (sorbitan monooleate).

19. The method of claim 17, wherein the polyetheramine is a compound of formula (III): 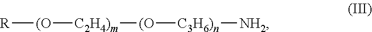
in which m is an integer from 0 to 40 representing the number of ethylene oxide groups; n is an integer from 0 to 40 representing the number of propylene oxide groups; R is a hydrocarbon chain, optionally substituted with a phenoxy group or an aryl group, or an NH₂ group.

20. The method of claim 17, wherein the polyetheramine is selected from the group consisting of diethylene glycol diamine, poly(ethyleneoxy)amine (e.g., JEFFAMINE© EDR-148), poly(propyleneoxy)amine (e.g., JEFFAMINE® T-403, Polyetheramine T-5000), polyetheramine M-2005 (JEFFAMINE® M-2005), polyetheramine M-2070 (JEFFAMINE® M-2070), Surfonamine® B-60, α-(2-Aminomethylethyl)-ω-(nonylphenoxy)-poly[oxy(methyl-1,2-ethanediyl (Surfonamine® B-100), and Surfonamine® B-200.

21. The method of claim 15, wherein the at least one silicate dispersant comprises an anionic surfactant selected from the group consisting of carboxylate surfactants, sulfonate surfactants, phosphate surfactants, sulfate surfactants and mixtures thereof.

22. The method of claim 15, wherein the at least one silicate dispersant is in an amount of from about 0.0001 wt % to about 1 wt % of the composition.

23. The method of claim 1, wherein the at least one pH adjusting agent is selected from organic bases, inorganic bases, or combinations thereof.

24. The method of claim 1, wherein the at least one pH adjusting agent is in an amount of from about 0.01 wt % to about 5 wt % of the composition.

25. The method of claim 1, wherein the composition does not include an oxidizing agent.
